(19) United States
(12) Patent Application Publication
(10) Pub. No.: US 2007/0004174 A1
(43) Pub. Date: Jan. 4, 2007

(54) Semiconductor wafer sawing system and method

(76) Inventor: John Paul Harris JR., Whitewright, TX (US)

Correspondence Address: TEXAS INSTRUMENTS INCORPORATED, P O BOX 655474, M/S 3999, DALLAS, TX, 75265, US

(21) Appl. No.: 11/172,974

(22) Filed: Jul. 1, 2005

(51) Int. Cl. H01L 21/00

(52) U.S. Cl. 438/460; 257/E21.238

(57) ABSTRACT

The invention provides methods and systems for sawing and singulating individual semiconductor devices manufactured on a wafer. Pursuant to the systems and methods of the invention, a wafer is secured for sawing and is then presented to a saw blade. At least one parameter associated with sawing the wafer is monitored and the rate of presentation of the wafer to the saw blade is dynamically controlled responsive to the one or more monitored parameters. According to preferred embodiments of the invention, the saw blade voltage or spindle current is a monitored parameter. Additional monitored parameters include horizontal and vertical forces acting upon the wafer and deflection of the saw blade. In preferred embodiments of the invention, monitored sawing process parameters are also used to establish control limits, which are then used to implement real time process controls.

### TECHNICAL FIELD

The invention relates to the manufacture of semiconductor devices. More particularly, the invention relates to methods and systems for saw singulation in the manufacture of semiconductor devices.

### BACKGROUND OF THE INVENTION

It is known to fabricate numerous semiconductor devices on a wafer and subsequently singulate the devices for final testing and packaging. Singulation may be accomplished by sawing, or by partial sawing combined with controlled breaking along the saw kerfs, also known as scribing and breaking. Generally, the wafer singulation process includes steps for aligning the wafer in a position for cutting, and then sawing through, or partially through, the wafer along prepared singulation or saw streets according to predetermined die dimensions. The sawing is performed using a metallized or resin-bonded diamond disc saw blade rotating at a high speed. After singulation, the devices undergo further processing such as cleaning, testing, and packaging.

Because semiconductor wafers upon which individual semiconductor devices are fabricated are generally disc-shaped, a saw blade coming into contact with the edge of the wafer upon entry or exit may be deflected horizontally. The degree of deflection is largely dependent upon the angle of the saw blade entry relative to the edge of the wafer. Sawing in a line nearly perpendicular to the edge of the wafer may result in little or no deflection. Sawing in an angle oblique to the edge of the wafer may induce more pronounced deflection. The deflection of the saw blade can result in damage to devices, for example by causing the saw blade to stray from the saw street and cut into the wrong location, or induce increased chipping caused by deviation from a straight saw path. Also, the saw blade itself may be damaged by deflection-induced stresses or may experience uneven wear. It is known in the arts to use a slow table rate, the rate at which the wafer is presented to the cutting edge of the saw blade, in order to reduce the effects of deflection. This solution is somewhat effective at reducing the above problems at the expense of throughput rate. Another approach is to provide wider saw streets between the devices on the wafer. Wider saw streets provide a greater margin of protection by allowing for some deviation in the cut, and for chipping. Using wider saw streets also permits the use of thicker saw blades, which may be more resistant to deflection. A major problem with this approach, however, is the loss of useable space on the wafer due to the increase in sacrificial material between devices.

Due to these and other problems related to wafer sawing and device singulation, it would be beneficial to implement improved methods and systems for sawing with reduced potential for damage to singulated devices. Such improvements would be particularly advantageous if they could be accomplished without reducing device density, and without reducing throughput rate. Further advantages could potentially be realized in the form of improved saw control, resulting in reduced waste and longer blade life.

### SUMMARY OF THE INVENTION

In carrying out the principles of the present invention, in accordance with preferred embodiments thereof, the invention provides methods and systems for sawing and singulating individual devices from a semiconductor wafer.

According to an aspect of the invention, in a preferred embodiment, a method is provided in which a wafer is secured for sawing and is then presented to a saw blade. At least one parameter associated with sawing the wafer is continuously monitored and the rate of presentation of the wafer to the saw blade is dynamically controlled responsive to the one or more monitored parameters.

According to another aspect of the invention, a step of monitoring the saw blade spindle current is included.

According to yet another aspect of the invention, a step of monitoring the saw blade motor voltage is included.

According to still another aspect of the invention, a semiconductor wafer sawing system provides means for securing a wafer for sawing and for monitoring at least one parameter associated with sawing the wafer. Means are also included for presenting the wafer to a saw blade for sawing at a rate dynamically responsive to the monitored parameter.

According to further aspects of the invention, wafer sawing systems according to preferred embodiments of the invention further include means for monitoring the sawing parameters and means for using the monitored data for controlling the sawing process.

The invention has advantages including but not limited to potential for higher quality cuts, improved throughput, higher density of devices per wafer, higher yield, reduced waste, longer saw blade life, and decreased costs. These and other features, advantages, and benefits of the present invention can be understood by one reasonably skilled in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top view of a glass-bonded semiconductor wafer with assembled unsingulated devices illustrating an example of the systems and methods of the invention;

FIG. 2 is a simplified block diagram depicting an overview of examples of systems and methods according to preferred embodiments of the invention;

FIG. 3 is a graphical depiction of an example of sawing parameters according to preferred embodiments of the invention; and

FIG. 4 is a graphical depiction of another example of sawing parameters according to preferred embodiments of the invention.

References in the detailed description correspond to like references in the various drawings unless otherwise noted. Descriptive and directional terms used in the written description such as first, second, top, bottom, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

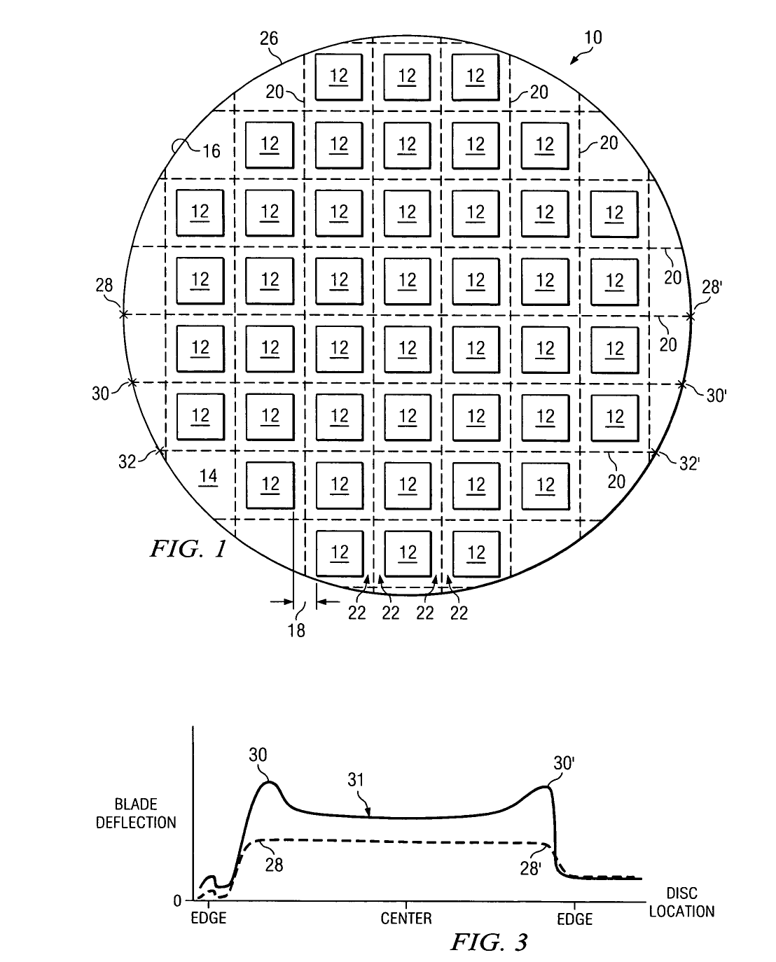

Referring primarily to FIG. 1, a top view of a semiconductor wafer 10 is shown with numerous assembled unsingulated devices 12. Typically, upon completion of the fabrication of the individual devices 12, the wafer 10 surfaces 14, 16, are uniformly smooth. During fabrication, area 18 is provided between the active areas of the devices 12, which typically includes saw streets 20 reserved to allow for singulation, and an inactive area 22 at the edges of each device 12 in order to provide a margin for protection of the interior portion of the device 12 during further processing and after singulation. The arrangement and number of devices shown provides those reasonably familiar with the arts a context and framework sufficient for the description of exemplary embodiments of methods and devices of the invention, and is not intended to be descriptive of any particular size, number, or arrangement of devices, nor of any specific wafer. For example, the wafer may be a common silicon wafer, or a glass-bonded wafer.

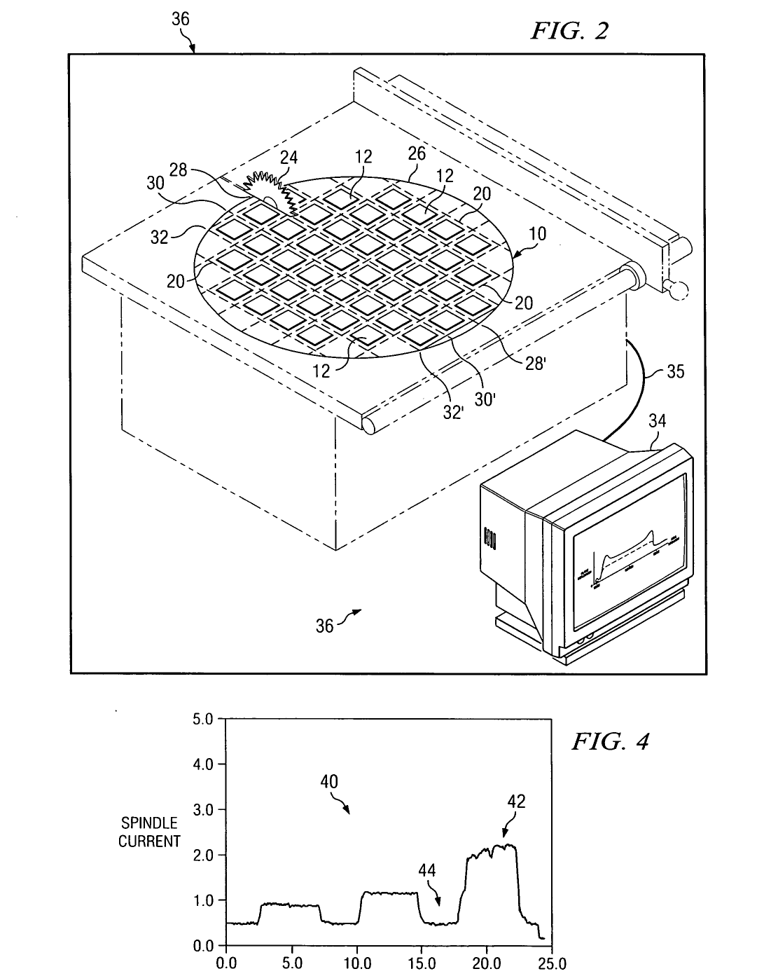

Now also referring to FIG. 2, the systems and methods of the invention are depicted in a simplified conceptual block diagram. The wafer 10 is preferably held securely and presented to the saw blade 24 as known in the arts. It can be seen by comparison of the saw streets 20, that although the saw blade 24 enters perpendicular to the plane of the wafer 10 at all locations, the angle at which the edge 26 of the wafer 10 meets the plane of the saw blade 24 may vary from nearly perpendicular as indicated at 28, to oblique as shown for example, at 30 and 32. It should be appreciated by those familiar with the arts, that the saw blade 24 will be affected differently when it encounters the edge 26 of the wafer 10 at different angles, e.g., 28, and 30; the tendency of the saw blade 24 to be deflected at location 30 is more pronounced than at 28.

Referring now to FIG. 3 as well, a graphical representation depicts examples of measured deflection forces 31 acting upon the saw blade at the various locations 28, 30, due to the angle of entry. It can be seen that the tendency to deflect is greater at the more oblique angle 30, than at the more nearly perpendicular angle 28 of entry. Also, the same effect is realized at the exit of the blade from the wafer material, the disc shape of the wafer 10 ordaining that the angle of exit, denoted 28′, 30′, is the reciprocal of the respective angle of entry, 28, 30.

The methods and systems of the present inventions provide decreased saw blade deflection and increased efficiency by dynamically monitoring and adapting sawing parameters including those associated with the entry and exit angles. Referring once more to the simplified overview of systems and methods for the implementation of the invention shown in FIG. 2, the wafer 10 to be sawn is held in place, preferably by suitable mounting means (not shown) as known in the art. The forces experienced during sawing are preferably monitored at the wafer 10 using suitable means such as one or more strain gauges (not shown). Deflection may also be measured at the saw blade 24. The physical resistance met by the saw blade 24 may also be inferred by monitoring the voltage across the saw motor, or the spindle current as represented by the display indicated at numeral 34. Preferably, multiple parameters relating to the sawing process are monitored simultaneously. The parameters thus monitored, such as blade deflection, vertical force on the wafer, voltage, and spindle current, are preferably fed back 35 into the system 36 in order to control sawing process. For example, in a preferred method of the invention, the blade entrance table rate, or rate at which the wafer 10 is presented to the saw blade 24, is controlled responsive to the saw blade spindle current, motor voltage, deflection.

Thus, as the saw blade 24 encounters increased resistance at the wafer 10, the table rate may be slowed, and as the resistance decreases the table rate may be increased. The dynamic control of the rate at which the wafer 10 is presented to the saw blade 24 facilitates spinning the saw blade 24 at a constant rate. In this way, since the table rate may be adjusted from cut-to-cut, and also from wafer edge-to-edge within each cut, high quality saw cuts and efficient throughput rates may be obtained.

Exemplary blade deflection and spindle current monitoring results are depicted in FIGS. 3 and 4, demonstrating how the monitored parameters may be used to dynamically control the sawing process. FIG. 3 has been discussed above. FIG. 4 is a graphical representation of how the spindle current 40 may be affected by changes in the resistance encountered by the saw blade during sawing. Periods of increased spindle current, e.g. 42, indicate an increased load due to the physical resistance encountered by the saw blade. Periods of decreased spindle current, e.g. 44, indicate less physical resistance. According to the invention, monitoring the spindle current 40 enables the dynamic adjustment of the table rate to ensure quality cuts and efficient throughput. Preferably, the table rate is increased when low spindle current 44 is indicated, and decreased during periods of high spindle current 42.

Additionally, the monitored parameters are preferably also used in conjunction with inspection of the sawing process output in order to establish control limits for the sawing process. Thus, the real-time monitored parameters may be compared during sawing with parameters predetermined to be within acceptable limits. Departure from acceptable limits may be used to make automatic adjustments to selected parameters, to trigger a warning signal, or to shut down the sawing process to allow a human operator to intervene. The increased level of dynamic control may provide additional advantages in preventing defective devices that might otherwise remain undetected during the completion of the sawing process, ultimately increasing overall yield and throughput and reducing costs.

The methods and systems of the invention provide advantages including but not limited to providing sawing methods with improved saw blade control and increased longevity. While the invention has been described with reference to certain illustrative embodiments, those described herein are not intended to be construed in a limiting sense. Various modifications and combinations of the illustrative embodiments as well as other advantages and embodiments of the invention will be apparent to persons skilled in the arts upon reference to the drawings, description, and claims.

1. A semiconductor wafer sawing method comprising:
securing a wafer for sawing;
presenting the wafer to a saw blade for sawing;
during sawing, monitoring at least one parameter associated with sawing the wafer;
controlling the presentation of the wafer to the saw blade at a rate dynamically responsive to at least one monitored parameter.

2. A semiconductor wafer sawing method according to claim 1 wherein at least one monitored parameter comprises horizontal force acting upon the wafer.

3. A semiconductor wafer sawing method according to claim 1 wherein at least one monitored parameter comprises vertical force acting upon the wafer.

4. A semiconductor wafer sawing method according to claim 1 wherein at least one monitored parameter comprises vertical force acting upon saw blade.

5. A semiconductor wafer sawing method according to claim 1 wherein at least one monitored parameter comprises spindle current associated with the saw blade.

6. A semiconductor wafer sawing method according to claim 1 wherein at least one monitored parameter comprises voltage across a saw motor associated with the saw blade.

7. A semiconductor wafer sawing method according to claim 1 wherein at least one monitored parameter comprises horizontal deflection forces acting upon the saw blade.

8. A semiconductor wafer sawing method according to claim 1 further comprising the step of determining one or more control limit using at least one monitored parameter.

9. A semiconductor wafer sawing method according to claim 1 further comprising the step of dynamically controlling the sawing process responsive to comparison of one or more monitored parameter with one or more control limit.

10. A semiconductor wafer sawing system comprising:
means for securing a wafer for sawing;
means for monitoring at least one parameter associated with sawing the wafer;
means for introducing the wafer to a saw blade for sawing at a rate dynamically responsive to at least one monitored parameter.

11. A semiconductor wafer sawing system according to claim 10 further comprising means for monitoring horizontal force acting upon the wafer.

12. A semiconductor wafer sawing system according to claim 10 further comprising means for monitoring vertical force acting upon the wafer.

13. A semiconductor wafer sawing system according to claim 10 further comprising means for monitoring vertical force acting upon saw blade.

14. A semiconductor wafer sawing system according to claim 10 further comprising means for monitoring spindle current associated with the saw blade.

15. A semiconductor wafer sawing system according to claim 10 further comprising means for monitoring voltage across a saw motor associated with the saw blade.

16. A semiconductor wafer sawing system according to claim 10 further comprising means for monitoring horizontal deflection forces acting upon the saw blade.

17. A semiconductor wafer sawing system according to claim 10 further comprising means for computing one or more control limit using at least one monitored parameter.

18. A semiconductor wafer sawing system according to claim 10 further comprising means for dynamically controlling the sawing process responsive to comparison of one or more monitored parameter with one or more predetermined control limit.
